(19) United States
(12) Patent Application Publication
(10) Pub. No.: US 2014/0158944 A1
(43) Pub. Date: Jun. 12, 2014

(54) POLYANILINE COMPOSITES AND FABRICATION METHOD THEREOF

(71) Applicant: National Tsing Hua University, Hsinchu (TW)

(72) Inventors: Nyan-Hwa TAI, Hsinchu (TW); Yin-Ju CHEN, Hsinchu (TW)

(73) Assignee: National Tsing Hua University, Hsinchu (TW)

(21) Appl. No.: 14/086,307

(22) Filed: Nov. 21, 2013

(30) Foreign Application Priority Data
Dec. 11, 2012 (TW) 101146597

(51) Int. Cl. H05K 9/00

(52) U.S. Cl. CPC H05K 9/0081
USPC 252/478

(57) ABSTRACT

Polyaniline composites comprise a major matrix and fillers. The major matrix is polyaniline having electrical conductivity. The fillers are used to fill the matrix. The fillers comprise carbon materials and metal materials. For example, carbon materials can be graphene, carbon nanotubes or combination thereof. The metal materials are attached to or embedded on the carbon materials. Besides, a method for fabricating polyaniline composites is also provided. By decorating the carbon materials with the metal materials, conductivity and electromagnetic shielding efficiency of the polyaniline composites are enhanced significantly.

### BACKGROUND OF THE INVENTION

1. Field of the Invention

The present invention relates to polyaniline composites and fabrication method thereof, and more particularly to polyaniline composites having good electromagnetic shielding properties and fabrication method thereof.

2. Description of the Prior Art

Nowadays, electronic products are indispensable elements in human's life, such as mobile phones or tablet personal computers. These electronic products have features of small size with multi functions, high processing speed and multi-band frequency. In this regard, electromagnetic interference becomes a severe problem for the modern electronic products. There are two sources of electromagnetic interference; one is internal electromagnetic interference between internal components of electronic products due to high component density, the other one is external electromagnetic interference caused by electronic products coming from public places such as offices, campus or public transportation. To solve this problem, developing high performance electromagnetic shielding techniques and materials for the modern electronic products is imperative.

In the aspect of national defense or aerospace technology, electromagnetic shielding materials can also be applied to keep stealth of navigation system and protect facilities from electromagnetic pulse attack, etc. On the one hand, electromagnetic shielding materials can prevent precision instruments from external electromagnetic interference and block electromagnetic waves emitted outward; on the other hand, electromagnetic radiation may cause harm to people's health and induce lesions such as endocrine disorders. As a solution, building materials for electromagnetic shielding can provide useful protection against electromagnetic radiation.

Absorption loss and reflection loss of incident electromagnetic waves contribute to electromagnetic shielding efficiencies. Generally, materials having high electric conductivity possess higher electromagnetic shielding efficiency. However, inner voids in materials may provide a path for electromagnetic waves to pass through and therefore reduce electromagnetic shielding efficiency. To make a balance between conductivity and material structure, polyaniline which is electrically conductive material has become a promising material to fabricate electromagnetic shielding materials. Additionally, polyaniline has other desired features such as low weight, high toughness, easy processing and adjustable conductivity, and these features render it a potential material for electromagnetic shielding. However, as a high performance electromagnetic shielding material, conductivity of polyaniline seems less ideal.

Therefore, it is a good strategy to increase electrical conductivity of polyaniline for performing better electromagnetic shielding efficiency.

### SUMMARY OF THE INVENTION

A polyaniline composite and fabrication method thereof is provided here. One of the conductive polymers, polyaniline (PAni), is adopted as major matrix. Carbon materials decorated with different weight percentage of metal materials, such as graphene decorated with silver (Ag@graphene) or nickel nanoparticles (Ni@graphene), are added and mixed with polyaniline to fabricate polyaniline composites. Choosing polyaniline is because that polyaniline possesses high electrical conductivity, as compared with the non-conductive polymer. By introducing conductive materials (e.g. Ag@graphene or Ni@graphene) into polyaniline, the conductivity of the polyaniline composites can be further improved, as a result, the electromagnetic shielding efficiency can be enhanced.

According to an embodiment of the present invention, a polyaniline composite comprises a major matrix and a filler. The major matrix is composed of polyaniline which is electrically conductive. The filler is distributed in the major matrix or attached to the major matrix. The filler comprises a carbon material and a metal material. The carbon material comprises carbon nanomaterials such as graphene, carbon nanotubes or combination thereof. The metal material is attached to the carbon matrix, embedded in the carbon material, or distributed in the major matrix.

According to another embodiment of the present invention, a method for fabricating polyaniline composites comprises steps is listed as follows: preparing a filler, wherein the filler comprises a carbon material and a metal material, and the metal material is attached to the carbon material, embedded in the carbon material, or distributed in the major matrix; and using a aniline monomer solution containing aniline monomers to synthesize a major matrix, wherein the major matrix is composed of polyaniline, and the filler is distributed in the major matrix or attached to the major matrix. To fabricate the polyaniline composites, the filler is introduced to aniline monomer solution for polymerization.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

FIG. 1 is a schematic diagram illustrating metal particles attached to or embedded in graphene;

FIG. 2 is a plot displaying imaginary part of permittivities of pure polyaniline and polyaniline composites;

FIG. 3A and FIG. 3B display, respectively, SEM morphologies of Ag@graphene and Ni@graphene;

FIG. 4A and FIG. 4B display, respectively, SEM morphologies of polyaniline composites comprising Ag@graphene and Ni@graphene; and

FIG. 5 is a schematic diagram illustrating metal particles attached to, embedded in or intercalated between graphene.

### DESCRIPTION OF THE PREFERRED EMBODIMENT

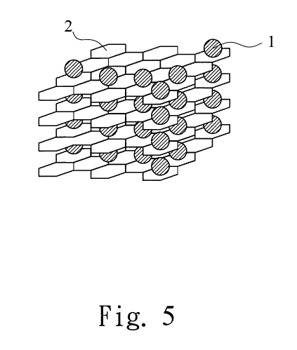

According to an embodiment of the present invention, a polyaniline composite comprises a major matrix and a filler. The major matrix is composed of polyaniline which is electronically conductive. The filler is distributed inside the major matrix or attached to the major matrix. The weight percentage of the filler is between 0.1% and 10% of the polyaniline composite, preferably, between 0.5% and 5%. The filler comprises a carbon material and a metal material. The carbon material comprises carbon nanomaterials such as graphene or carbon nanotubes or combination thereof. As for the metal material, it comprises at least one of silver, nickel, gold, copper, platinum, and palladium. The metal material in the form of nanoparticles is attached to or embedded in the carbon material or distributed in the major matrix. In one embodiment of the present invention, graphene is decorated with silver (Ag@graphene) or decorated with nickel (Ni@graphene), etc. As shown in FIG. 1, metal particles 1 are attached to or embedded in graphene 2. Preferably, multilayer graphene (e.g. 4 to 5 layers) is used in the present invention. As shown in FIG. 5, it illustrates a four layer structure of graphene. Metal particles 1 are attached to, embedded in or intercalated between graphene 2.

According to another embodiment of the present invention, a method for fabricating polyaniline composites comprising steps is stated as follows: preparing a filler, wherein the filler comprises a carbon material and a metal material, wherein the metal material is attached to the carbon matrix, embedded in the carbon material, or distributed in the major matrix; using a aniline monomer solution containing aniline monomers to synthesize a major matrix, wherein the major matrix is composed of polyaniline, and the filler is distributed in the major matrix or is attached to the major matrix. Features, composition and structure of these components are described before and will not be elaborated here. The method for fabricating these materials will be described in details hereinafter.

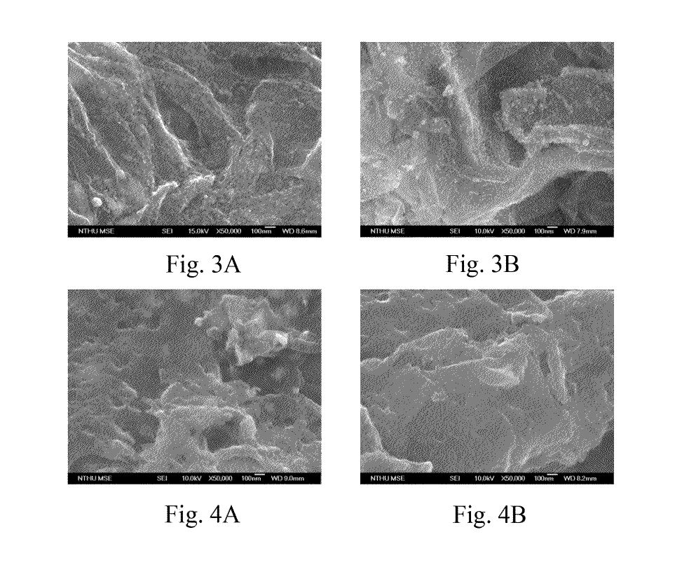

In one embodiment, the step of preparing the filler contains mixing the carbon materials, a precursor of the metal material and a reducing agent together to synthesize the metal materials attached to or embedded in the carbon materials or combination thereof. If the carbon material comprises graphene, according to one embodiment of the present invention, graphene must be synthesized before the step. The modified Hummer's method is adopted to synthesize graphite oxide (GO), which includes the intercalation of H₂SO₄ into the interspace between graphite layers followed by introducing KMnSO₄ and subsequently adding H₂O₂ into the solution; all the processes are carried out under stirring. Afterward, the solution comprising GO is mixed with AgNO₃ solution under stirring. Subsequently, a reducing agent, such as NaBH₄ solution is added to reduce graphite oxide under reflux so as to obtain graphene. Meanwhile, silver in AgNO₃ solution is reduced and the silver nanoparticles are attached to or embedded in graphene. Nickel or other metal materials can also be fabricated using the similar route, which are attached to or embedded in graphene. Besides, according to another embodiment of the present invention, the step of preparing the filler further comprises functionalizing the surface of the carbon materials to facilitate the metal materials to react with the carbon materials. For example, commercialized available graphene can be directly mixed with H₂SO₄ and KMnSO₄ under ultrasonication at room temperature. Afterward, HCl is added into the solution under stirring and heating for functionalizing the graphene surface, which enables graphene to bind metal nanoparticles easily. Subsequently, the precursor of metal material is added to the graphene solution, the metal material can be deposited and/or embedded on the graphene. FIG. 3A and FIG. 3B show SEM (scanning electron microscope) images of Ag@graphene and Ni@graphene, respectively. They clearly show that nanoparticles of the metal materials are distributed on graphene.

Next, an aniline monomer solution is mixed with the said filler to fabricate polyaniline composites. Synthesis of polyaniline is conventionally known and will not be elaborated here. According to the present invention, there are two major methods to synthesize polyaniline composite. In one embodiment, the filler is firstly dispersed in solvent followed by mixing with the aniline monomer solution so that the filler reacts with the aniline monomers to synthesize the polyaniline composites. In the mean time, the filler is distributed in the major matrix or attached to the major matrix. In another embodiment, the aniline monomer solution is used to synthesize the major matrix and then mixed with a first solution comprising the filler so that the filler can be distributed in the major matrix or attached to the major matrix. It should be understood that the polyaniline composite fabricated by the aforementioned method has better dispersion. The SEM images shown in FIG. 4A and FIG. 4B illustrate morphologies of polyaniline composites comprising Ag@graphene and Ni@graphene, respectively.

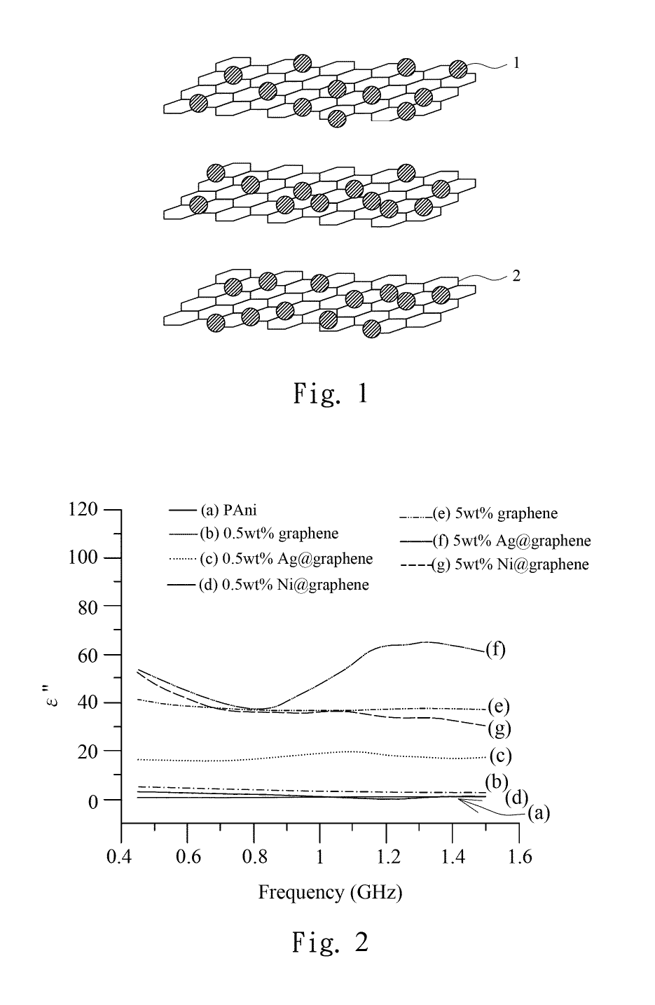

Graphene decorated with metal particles distributed in or attach on polyaniline can promote electrical conductivity of the polyaniline composite. Conventionally, better conductivity means higher mobility of free electrons, which causes skin effect of electronic currents. Taking electromagnetic waves for example, when it pass through the polyaniline composite of the present invention, electrons over the surface of the composite would be polarized, which reduces the strength of the electromagnetic wave and leads to better electromagnetic shielding efficiency. Based on the method for fabricating polyaniline composites according to one embodiment of the present invention, by adding graphene decorated with metal nanoparticles to the polyaniline composites, its imaginary part of the dielectric coefficient is superior to that of pure polyaniline and polyaniline composites containing graphene. The results shown in FIG. 2 illustrating that the polyaniline composite containing 5 wt % Ag@graphene has the highest dielectric coefficient.

To expound it clearly, electromagnetic shielding efficiencies of the fabricated polyaniline composite according to the present invention, pure polyaniline (PAni), and polyaniline composites containing different weight percentages of graphene are listed in Table 1.

TABLE 1
Comparison on electromagnetic shielding
efficiencies of polyaniline composites

| | Weight percentage | | | | | |
|---|---|---|---|---|---|---|
| | 0.5 wt % | | | 1.0 wt % | | |
| filler | SE_{A} | SE_{R} | SE_{T} | SE_{A} | SE_{R} | SE_{T} |
| Graphene | 12.65 | 3.11 | 15.76 | 12.97 | 4.02 | 16.99 |
| Ag@graphene | 17.96 | 2.21 | 20.17 | 16.87 | 5.08 | 21.95 |
| Ni@graphene | 13.26 | 3.89 | 17.15 | 14.74 | 3.29 | 18.03 |
| | 3.0 wt % | | | 5.0 wt % | | |
| filler | SE_{A} | SE_{R} | SE_{T} | SE_{A} | SE_{R} | SE_{T} |
| Graphene | 17.67 | 2.29 | 19.96 | 23.94 | 0.91 | 24.85 |
| Ag@graphene | 18.63 | 3.65 | 22.28 | 24.13 | 5.20 | 29.33 |
| Ni@graphene | 17.85 | 2.52 | 20.77 | 22.12 | 2.81 | 24.93 |

*formula of electromagnetic shielding efficiency: SE_{T}(total efficiency) = SE_{A}(absorption loss) + SE_{R}(reflection loss)
*For pure polyaniline: SE_{A} = 10.25 dB, SE_{R} = 4.27 dB, SE_{T} = 14.52 dB

Based on the data shown in Table 1, comparisons on the electromagnetic shielding efficiencies of the polyaniline composites are: PAni+5% Ag@graphene (29.33 dB)>PAni+5% Ni@graphene (24.93 dB)>PAni+5% graphene (24.85 dB)>pure PAni (14.52 dB). Obviously, the polyaniline composite of the present invention (PAni+5% Ag@graphene) has the best electromagnetic shielding efficiency (29.33 dB) which is applicable for industrial application.

In conclusion, a polyaniline composite and a fabrication method thereof are provided here. One of the conductive polymers, polyaniline, is adopted as major matrix. Carbon materials decorated with different weight percentages of metal materials, such as graphene decorated with silver (Ag@graphene) or nickel nanoparticles (Ni@graphene), are added and mixed with polyaniline synthesize polyaniline composites. Choosing polyaniline is owing to its relatively high electrical conductivity. By introducing conductive materials (e.g. Ag@graphene or Ni@graphene) into polyaniline matrix, the electrical conductivity of the composites can be promoted; as a result, electromagnetic shielding efficiency is enhanced. According to the experimental data, the composites fabricated according to the present invention show better performance in electromagnetic shielding efficiency.

While the invention is susceptible to various modifications and alternative forms, a specific example thereof has been shown in the drawings and is herein described in detail. It should be understood, however, the invention is not to be limited to the particular form disclosed, but to the contrary, the invention is to cover all modifications, equivalents, and alternatives falling within the spirit and scope of the appended claims.

What is claimed is:

1. A polyaniline composite comprises:
a major matrix, which is composed of polyaniline, wherein polyaniline is an electrically conductive material; and
a filler, which is distributed in the major matrix or attached to the major matrix, wherein the filler comprises:
a carbon material, which comprises carbon nanomaterials; and
a metal material, which is attached to the carbon material, embedded in the carbon material, or distributed in the major matrix.

2. The polyaniline composite according to claim 1, wherein the metal material comprises at least one of silver, nickel, gold, copper, platinum and palladium.

3. The polyaniline composite according to claim 1, wherein the weight percentage of the filler in the polyaniline composite is in the range of 0.1% to 10%.

4. The polyaniline composite according to claim 1, wherein the carbon nanomaterials comprise graphene or carbon nanotubes or combination thereof.

5. The polyaniline composite according to claim 1, wherein the metal material is in the form of nanoparticles.

6. A method for fabricating polyaniline composites comprising:
preparing a filler, wherein the filler comprises a carbon material and a metal material, wherein the metal material is attached to the carbon material, embedded in the carbon material, or distributed in the major matrix; and
using an aniline monomer solution containing aniline monomers to synthesize a major matrix, wherein the major matrix is composed of polyaniline, and the filler is distributed in the major matrix or attached to the major matrix.

7. The method for fabricating polyaniline composites according to claim 6, wherein the step of preparing the filler is mixing the carbon materials, a precursor of the metal material, and a reducing agent to make the metal materials attached to the carbon materials or embedded in the carbon materials.

8. The method for fabricating polyaniline composites according to claim 6, wherein the carbon materials are functionalized to facilitate the metal materials to react with the carbon materials.

9. The method for fabricating polyaniline composites according to claim 6, wherein the filler is firstly dispersed in a solvent followed by mixing with the aniline monomer solution so that the filler reacts with the aniline monomers to form the polyaniline composites, wherein the filler is distributed in the major matrix or attached to the major matrix.

10. The method for fabricating polyaniline composites according to claim 6, wherein the aniline monomers of the aniline monomer solution are used for synthesizing the major matrix first and then mixed with a first solution containing the filler so that the filler is distributed in the major matrix or attached to the major matrix.

11. The method for fabricating polyaniline composites according to claim 6, wherein the metal materials comprises at least one of silver, nickel, gold, copper, platinum and palladium.

12. The method for fabricating polyaniline composites according to claim 6, wherein the weight percentage of the filler in the polyaniline composite is in the range of 0.1% to 10%.

13. The method for fabricating polyaniline composites according to claim 6, wherein the carbon material comprises graphene or carbon nanotubes, or combination thereof.

14. The method for fabricating polyaniline composites according to claim 6, wherein the metal material is in the form of nanoparticles.
